(19) United States
(12) Patent Application Publication
(10) Pub. No.: US 2005/0158883 A1
(43) Pub. Date: Jul. 21, 2005

(54) Multilayered structure film and method of making the same

(75) Inventor: Ryoichi Mukai, Kawasaki (JP)

Correspondence Address: Patrick G. Burns, Esq.;GREER, BURNS & CRAIN, LTD., Suite 2500, 300 South Wacker Dr., Chicago, IL, 60606, US

(73) Assignee: FUJITSU LIMITED

(21) Appl. No.: 11/068,638

(22) Filed: Feb. 28, 2005

Related U.S. Application Data
(63) Continuation of application No. PCT/JP03/02552, filed on Mar. 5, 2003.

(51) Int. Cl. H01L 21/00; H01L 21/44

(52) U.S. Cl. 438/3

(57) ABSTRACT

First atoms are subjected to heat treatment after deposition so as to form a first polycrystalline layer. Second atoms are deposited on the surface of the first polycrystalline layer so as to form a second polycrystalline layer having a thickness larger than that of the first polycrystalline layer. The method enables a reliable prevention of migration of the first atoms during the deposition of the first atoms. Since the first atoms are only allowed to deposit at a smaller amount relative to the overall thickness of a multilayered structure film, fine and uniform crystal grains can be established in the first polycrystalline layer. The deposition of the second atoms can be realized to a predetermined thickness without inducing migration. Fine and uniform crystal grains can also be established in the second polycrystalline layer. Enlargement of the crystal grains can reliably be avoided in this manner.

### BACKGROUND OF THE INVENTION

1. Field of the Invention

The present invention relates to a multilayered structure film often utilized for a magnetic recording layer of a magnetic recording medium such as a hard disk (HD), for example, and to a method of making the same.

2. Description of the Prior Art

In general, a magnetic recording medium includes a controlling underlayer extending on the surface of a substrate by a predetermined thickness, and a magnetic recording layer extending on the surface of the controlling underlayer by a predetermined thickness. The controlling underlayer serves to establish the orientation of the crystals in a predetermined direction in the magnetic recording layer. The axis of easy magnetization is thus aligned in a certain direction.

Sputtering is employed to form the controlling underlayer and the magnetic recording layer. The substrate is subjected to heat treatment prior to the execution of the sputtering. Metallic atoms for the controlling underlayer are deposited on the surface of the heated substrate. The heat serves to form crystal grains during the deposition of the metallic atoms. Metallic atoms for the magnetic recording layer are then deposited on the surface of the controlling underlayer. The magnetic crystal grains grow on the controlling underlayer based on the epitaxy.

The deposition of the metallic atoms is kept on the heated substrate until the controlling layer or the magnetic recording layer reaches a predetermined thickness. The applied heat causes the crystal grains to irregularly accrete in the controlling underlayer or the magnetic recording layer, so that the individual crystal grains get larger in size based on accretion. The magnetic recording layer cannot enjoy uniformity and reduction in size of the magnetic crystal grains.

### SUMMARY OF THE INVENTION

It is accordingly an object of the present invention to provide a multilayered structure film contributing to establishment of uniformity and reduction in size of crystal grains.

According to a first aspect of the present invention, there is provided a method of making a multilayered structure film, comprising: depositing first atoms on the surface of an object; subjecting the first atoms to heat treatment so as to form a first polycrystalline layer; and depositing second atoms on the surface of the first polycrystalline layer so as to form a second polycrystalline layer having a thickness larger than that of the first polycrystalline layer.

The method enables a reliable prevention of migration of the first atoms during the deposition of the first atoms. Since the first atoms are only allowed to deposit at a smaller amount relative to the overall thickness of the multilayered structure film, fine and uniform crystal grains can be established in the first polycrystalline layer. The deposition of the second atoms are then realized to a predetermined thickness without inducing migration. Fine and uniform crystal grains can also be established in the second polycrystalline layer. Enlargement of the crystal grains can reliably be avoided in this manner.

The first and second atoms may be Ti atoms in the method. Alternatively, the first and second atoms may form an alloy including Co and Cr. A vacuum condition should be kept between the deposition of the first atoms and the deposition of the second atoms.

The method may further comprise: depositing third atoms on the surface of the second crystalline layer; subjecting the third atoms to heat treatment so as to from a third crystalline layer; and depositing fourth atoms on the surface of the third polycrystalline layer so as to form a fourth polycrystalline layer having a thickness larger than that of the third polycrystalline layer. A vacuum condition should be kept between the deposition of the first atoms and deposition of the fourth atoms.

The method enables a reliable prevention of migration of the third atoms during the deposition of the third atoms. Since the third atoms are only allowed to deposit at a smaller amount relative to the overall thickness of the multilayered structure film, fine and uniform crystal grains can be established in the third polycrystalline layer. The deposition of the fourth atoms are then realized to a predetermined thickness without inducing migration. Fine and uniform crystal grains can also be established in the fourth polycrystalline layer. Enlargement of the crystal grains can reliably be avoided in this manner.

The method may further comprise covering the surface of the object, prior to the deposition of the first atoms, with a controlling layer including crystal grains oriented in a predetermined direction. The first and second polycrystalline layer may be formed on the controlling layer. The controlling layer thus serves to reliably align the orientation of the crystal grains in the first and second polycrystalline layers.

According to a second aspect of the present invention, there is provided a multilayered structure film comprising: a first polycrystalline layer including crystal grains adjacent each other; and a second polycrystalline layer including at least an element included in the first polycrystalline layer, said second polycrystalline layer extending on the surface of the first polycrystalline layer by a thickness larger than that of the first polycrystalline layer, wherein said second polycrystalline layer includes crystal grains growing from the crystal grains of the first polycrystalline layer. The multilayered structure film enables establishment of fine and uniform crystal grains in the first and second polycrystalline structure. In addition, the first and second polycrystalline layers are allowed to have a sufficient thickness.

The multilayered structure film may allow employment of Ti for the first and second polycrystalline layers. Alternatively, the first and second polycrystalline layers may be made of an alloy containing Co and Cr.

The multilayered structure film may further comprise a controlling layer receiving the first polycrystalline layer. The controlling layer includes crystal grains oriented in a predetermined direction. The controlling layer serves to reliably establish the alignment of the crystal grains in the first polycrystalline layer. Since the crystal grains of the second polycrystalline layer grows from the individual crystal grains in the first polycrystalline layer, the orientation of the crystal grains can reliably be set in a predetermined direction in the second polycrystalline layer.

The multilayered structure film may be utilized in a magnetic recording medium such as a magnetic recording disk, for example. In this case, the magnetic recording medium may comprise: a first non-magnetic polycrystalline underlayer including crystal grains adjacent each other; a second non-magnetic polycrystalline underlayer including at least an element included in the first non-magnetic polycrystalline underlayer, said second non-magnetic polycrystalline underlayer extending on the surface of the first non-magnetic polycrystalline underlayer by a thickness larger than that of the first non-magnetic polycrystalline underlayer; and a magnetic layer extending on the surface of the second non-magnetic polycrystalline underlayer. The second non-magnetic polycrystalline underlayer may include crystal grains growing from the crystal grains of the first non-magnetic polycrystalline underlayer.

The magnetic recording medium enables establishment of fine and uniform crystal grains in the first and second non-magnetic polycrystalline underlayers. In addition, the first and second non-magnetic polycrystalline underlayers are allowed to have a sufficient thickness. The axis of easy magnetization can thus reliably be aligned in the perpendicular direction perpendicular to the surface of the substrate in the magnetic layer. A higher signal-to-noise (S/N) ratio can be obtained.

The magnetic layer may comprise: a first magnetic polycrystalline layer including crystal grains adjacent each other on the surface of the second non-magnetic polycrystalline underlayer; a second magnetic polycrystalline layer including at least an element included in the first magnetic polycrystalline layer, said second magnetic polycrystalline layer extending on the surface of the first magnetic polycrystalline layer by a thickness larger than that of the first magnetic polycrystalline layer, wherein said second magnetic polycrystalline layer includes crystal grains growing from the crystal grains of the first magnetic polycrystalline layer.

The magnetic recording medium enables establishment of fine and uniform crystal grains in the first and second magnetic polycrystalline layers. In addition, the first and second magnetic polycrystalline layers are allowed to have a sufficient thickness. The axis of easy magnetization can thus reliably be aligned in the perpendicular direction perpendicular to the surface of the substrate in the first and second magnetic polycrystalline layers. A higher signal-to-noise (S/N) ratio can be obtained.

Alternatively, a magnetic recording medium may comprise: a non-magnetic polycrystalline underlayer; a first magnetic polycrystalline layer including crystal grains adjacent each other on the surface of the non-magnetic polycrystalline underlayer; a second magnetic polycrystalline layer including at least an element included in the first magnetic polycrystalline layer, said second magnetic polycrystalline layer extending on the surface of the first magnetic polycrystalline layer by a thickness larger than that of the first magnetic polycrystalline layer. The second magnetic polycrystalline layer may include crystal grains growing from the crystal grains of the first magnetic polycrystalline layer.

The magnetic recording medium of the type enables establishment of fine and uniform crystal grains in the first and second magnetic polycrystalline layers in the manner as described above. A higher signal-to-noise (S/N) ratio can likewise be obtained.

The aforementioned magnetic recording medium may be a so-called perpendicular magnetic recording medium, for example. The axis of easy magnetization maybe aligned in the perpendicular direction perpendicular to the surface of the substrate in the aforementioned magnetic layer or first and second magnetic polycrystalline layers. The perpendicular magnetic recording medium may further include a non-magnetic layer receiving the non-magnetic polycrystalline underlayer; and a magnetic underlayer receiving the non-magnetic layer, the magnetic underlayer having the axis of easy magnetization in a direction parallel to the surface of the non-magnetic polycrystalline underlayer.

### BRIEF DESCRIPTION OF THE DRAWINGS

The above and other objects, features and advantages of the present invention will become apparent from the following description of the preferred embodiment in conjunction with the accompanying drawings, wherein:

FIG. 1 is a plan view schematically illustrating the structure of a hard disk drive as an example of a magnetic recording medium drive or storage unit;

FIG. 2 is an enlarged vertical sectional view of a magnetic recording disk employed in the hard disk drive;

FIG. 3 is an enlarged vertical sectional view of the magnetic recording disk in detail;

FIG. 4 is an enlarged partial sectional view of the magnetic recording disk for schematically illustrating the process of forming a magnetic underlayer on the surface of a substrate;

FIG. 5 is an enlarged partial sectional view of the magnetic recording disk for schematically illustrating the process of forming a controlling layer on the surface of the magnetic underlayer;

FIG. 6 is an enlarged partial sectional view of the magnetic recording disk for schematically illustrating the process of forming a first non-magnetic polycrystalline underlayer on the surface of the controlling layer;

FIG. 7 is an enlarged partial sectional view of the magnetic recording disk for schematically illustrating the process of forming a second non-magnetic polycrystalline underlayer on the surface of the first non-magnetic polycrystalline underlayer;

FIG. 8 is an enlarged partial sectional view of the magnetic recording disk for schematically illustrating the process of forming a first magnetic polycrystalline layer on the surface of the second non-magnetic polycrystalline underlayer;

FIG. 9 is an enlarged partial sectional view of the magnetic recording disk for schematically illustrating the process of forming a second magnetic polycrystalline layer on the surface of the first magnetic polycrystalline layer;

FIG. 10 is a graph illustrating the orientation of crystal grains based on X-ray diffraction;

FIG. 11 is a graph illustrating the relationship between the thickness of the first non-magnetic polycrystalline under layer and the characteristic of the magnetic recording disk;

FIG. 12 is a graph illustrating the relationship between the thickness of the second non-magnetic polycrystalline underlayer and the characteristic of the magnetic recording disk;

FIG. 13 is a graph illustrating the orientation of crystal grains based on X-ray diffraction;

FIG. 14 is a graph illustrating the relationship between the thickness of the first magnetic polycrystalline layer and the characteristic of the magnetic recording disk;

FIG. 15 is a graph illustrating the orientation of crystal grains based on X-ray diffraction; and

FIG. 16 is a graph illustrating the orientation of crystal grains based on X-ray diffraction.

### DESCRIPTION OF THE PREFERRED EMBODIMENT

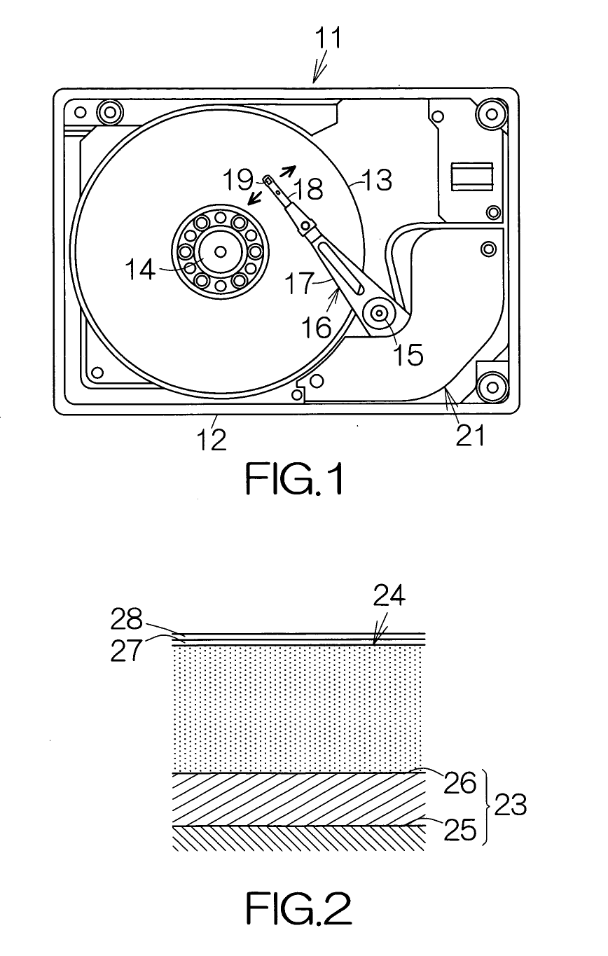

FIG. 1 schematically illustrates the interior structure of a hard disk drive (HDD) 11 as an example of a magnetic recording medium drive or storage device. The HDD 11 includes a box-shaped main enclosure 12 defining an inner space of a flat parallelepiped, for example. At least one magnetic recording disk 13 is incorporated in the inner space within the main enclosure 12. The magnetic recording disk or disks is formed as a so-called perpendicular magnetic recording medium. The magnetic recording disk or disks 13 is mounted on the driving shaft of a spindle motor 14. The spindle motor 14 is allowed to drive the magnetic recording disk 13 for rotation at a higher revolution rate such as 7,200 rpm, 10,000 rpm, or the like, for example. A cover, not shown, is coupled to the main enclosure 12 so as to define the closed inner space between the main enclosure 12 and itself.

A head actuator 16 is mounted on a vertical support shaft 15 in the inner space of the main enclosure 12. The head actuator 16 includes rigid actuator arms 17 extending in the horizontal direction from the vertical support shaft 15, and an elastic head suspension 18 fixed to the tip end of the actuator arm 17 so as to extend forward from the actuator arm 17. As conventionally known, a flying head slider 19 is cantilevered at the tip end of the head suspension 18 through a gimbal spring, not shown. The head suspension 18 serves to urge the flying head slider 19 toward the surface of the magnetic recording disk 13. When the magnetic recording disk 13 rotates, the flying head slider 19 is allowed to receive airflow generated along the rotating magnetic recording disk 13. The airflow serves to generate a lift on the flying head slider 19. The flying head slider 19 is thus allowed to keep flying above the surface of the magnetic recording disk 13 during the rotation of the magnetic recording disk 13 at a higher stability established by the balance between the lift and the urging force of the head suspension 18.

A read/write magnetic transducer or head element, not shown, is mounted on the flying head slider 19 in a conventional manner. The read/write magnetic transducer includes a read head element and a write head element. The read head element may include a giant magnetoresistive (GMR) element or a tunnel-junction magnetoresistive (TMR) element designed to discriminate magnetic bit data on the magnetic recording disk 13 by utilizing variation in the electric resistance of a spin valve film or a tunnel-junction film, for example. The write head element may include a single pole magnetic head designed to write magnetic bit data into the magnetic recording disk 13 by utilizing a magnetic field induced at a thin film coil pattern.

When the head actuator 16 is driven to swing about the support shaft 15 during the flight of the flying head slider 19, the flying head slider 19 is allowed to cross the recording tracks defined on the magnetic recording disk 13 in the radial direction of the magnetic recording disk 13. This radial movement serves to position the read/write magnetic transducer on the flying head slider 19 right above a target recording track on the magnetic recording disk 13. In this case, a power source 21 such as a voice coil motor (VCM) can be employed to realize the swinging movement of the head actuator 16, for example. As conventionally known, in the case where two or more magnetic recording disks 13 are incorporated within the inner space of the main enclosure 12, a pair of the actuator arm 17 and a pair of the head slider 19 are disposed between the adjacent magnetic recording disks 13.

FIG. 2 illustrates in detail the structure of the magnetic recording disk 13. The magnetic recording disk 13 includes a substrate 23 as a support member, and multilayered structure films 24 extending over the front and back surfaces of the substrate 23, respectively. The substrate 23 may comprise a disk-shaped Si body 25 and amorphous SiO₂ laminations 26 covering over the front and back surfaces of the Si body 25, for example. Alternatively, a glass or aluminum substrate may be employed in place of the substrate 23 of the aforementioned type. Magnetic information data is recorded in the multilayered structure films 24. The multilayered structure film 24 is covered with a protection overcoat 27 and a lubricating agent film 28. A carbon material such as diamond-like-carbon (DLC) may be utilized to form the protection overcoat 27. A perfluoropolyether (PFPE) film maybe employed as the lubricating agent film 28, for example.

As shown in FIG. 3, the multilayered structure film 24 includes a magnetic underlayer 31 extending over the surface of the substrate 23. The magnetic underlayer 31 is made of a soft magnetic material such as FeTaC, NiFe, or the like. Here, a FeTaC film having the thickness of 300 nm approximately is employed as the magnetic underlayer 31. The axis of easy magnetization is aligned in the planar direction parallel to the surface of the substrate 23 in the magnetic underlayer 31.

A controlling layer 32 extends on the upper surface of the magnetic underlayer 31. The controlling layer 32 includes crystal grains oriented in a predetermined direction. A non-magnetic layer such as a MgO layer may be employed as the controlling layer 32, for example. Here, a MgO layer having the thickness of 16.7 nm approximately is employed as the controlling layer 32. The (100) plane is oriented in a predetermined direction in the individual crystal grains of MgO.

The multilayered structure film 24 includes a first non-magnetic polycrystalline underlayer 33 extending on the surface of the controlling layer 32. The first non-magnetic polycrystalline underlayer 33 includes crystal grains adjacent each other on the controlling layer 32. Here, a Ti layer having a thickness in the range between 0.3 nm and 0.4 nm approximately may be employed as the first non-magnetic polycrystalline underlayer 33, for example.

The multilayered structure film 24 includes a second non-magnetic polycrystalline underlayer 34 extending on the upper surface of the first non-magnetic polycrystalline underlayer 33. The second non-magnetic polycrystalline underlayer 34 is designed to have a thickness larger than that of the first non-magnetic polycrystalline underlayer 33. The second non-magnetic polycrystalline underlayer 34 includes crystal grains growing from the individual crystal grains of the first non-magnetic polycrystalline underlayer 33 based on the epitaxy. The second non-magnetic polycrystalline underlayer 34 contains at least an element included in the first non-magnetic polycrystalline underlayer 33. Here, a Ti layer having a thickness in the range between 2.0 nm and 5.0 nm approximately is employed as the second non-magnetic polycrystalline underlayer 34, for example.

A first magnetic polycrystalline layer 35 extends on the upper surface of the second non-magnetic polycrystalline underlayer 34. The first magnetic polycrystalline layer 35 includes crystal grains adjacent each other on the surface of the second non-magnetic polycrystalline underlayer 34. An alloy containing Co and Cr may be utilized for the first magnetic polycrystalline layer 35, for example. Here, a CoCrPt layer having a thickness in the range between the 0.5 nm and 1.7 nm approximately is employed as the first magnetic polycrystalline layer 35. The (001) plane is oriented in a predetermined direction in the individual crystal grains of the first magnetic polycrystalline layer 35.

The multilayered structure film 24 further includes a second magnetic polycrystalline layer 36 extending on the upper surface of the first magnetic polycrystalline layer 35. The second magnetic polycrystalline layer 36 is designed to have a thickness larger than that of the first magnetic polycrystalline layer 35. The second magnetic polycrystalline layer 36 includes crystal grains growing from the individual crystal grains of the first magnetic polycrystalline layer 35 based on the epitaxy. The second magnetic polycrystalline layer 36 contains at least an element included in the first magnetic polycrystalline layer 35. Here, a CoCrPt layer having a thickness in the range between 5.8 nm and 7.5 nm approximately may be employed as the second magnetic polycrystalline layer 36, for example. The (001) plane is oriented in a predetermined direction in the crystal grains of the second magnetic polycrystalline layer 36. The axis of easy magnetization is thus established in the perpendicular direction perpendicular to the surface of the substrate 23. Magnetic information data is recorded in the first and second magnetic polycrystalline layers 35, 36.

Fine and uniform crystal grains are established in the first and second magnetic polycrystalline layers 35, 36. The fine crystalline grains serve to greatly reduce transition noise between the adjacent recording tracks on the surface of the magnetic recording disk 13. The first and second magnetic polycrystalline layers 35, 36 are still allowed to have a sufficient thickness. The axis of easy magnetization is reliably aligned in the perpendicular direction perpendicular to the surface of the substrate 23 with a higher accuracy. A higher signal-to-noise (S/N) ratio can be obtained.

Next, a detailed description will be made on a method of making the magnetic recording disk 13. First of all, the disk-shaped substrate 23 is prepared. The substrate 23 is set in a sputtering apparatus. A vacuum condition is established in a chamber of the sputtering apparatus. The multilayered structure film 24 is formed on the surface of the substrate 23 in the chamber of the sputtering apparatus. The processes will be described later in detail. The protection overcoat 27 is then formed on the surface of the multilayered structure film 24. Chemical vapor deposition (CVD) may be employed to form the protection overcoat 27. The lubricating agent film 28 is subsequently applied to the surface of the protection overcoat 27. The substrate 23 may be dipped into a solution containing perfluoropolyether, for example.

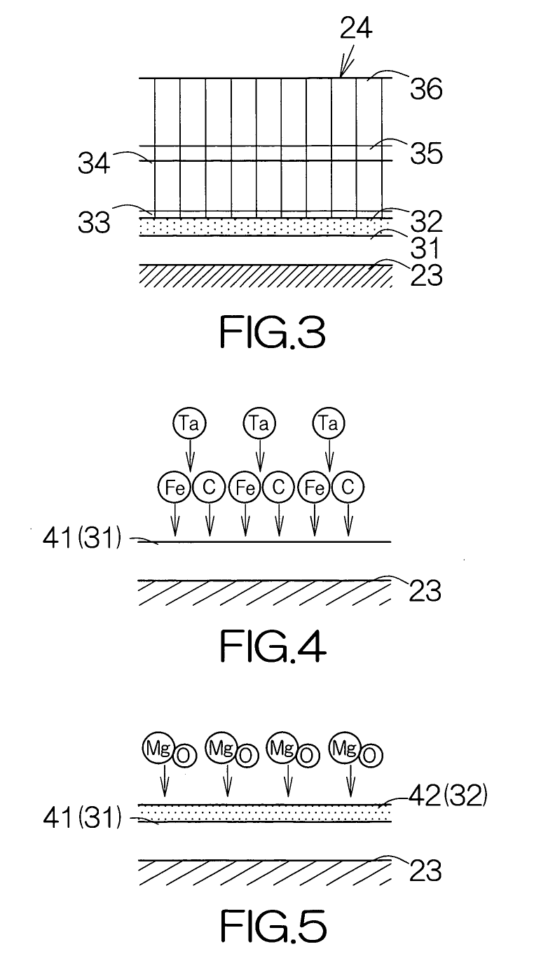

A FeTaC target is first set in the sputtering apparatus. As shown in FIG. 4, Fe atoms, Ta atoms and C atoms are evolved from the FeTaC target in the chamber in the vacuum condition. Specifically, a so-called radio or high frequency sputtering is effected in the sputtering apparatus. Fe atoms, Ta atoms and C atoms are allowed to deposit on the surface of the substrate 23. The normal or room temperature is kept during the deposition of the atoms in the chamber in this case. The magnetic underlayer 31, namely a FeTaC layer 41 having the thickness of 300 nm approximately, is thus formed on the surface of the substrate 23.

As shown in FIG. 5, MgO is subsequently deposited on the surface of the FeTaC layer 41 in the vacuum condition in the sputtering apparatus. The room temperature is kept in the chamber of the sputtering apparatus. The controlling layer 32, namely a MgO layer 42 having the thickness of 16.7 nm approximately, is thus formed on the surface of the FeTaC layer 41. Since the room temperature is kept in the chamber during the deposition of the MgO, the (100) plane is aligned in a predetermined direction in the individual non-magnetic crystal grains of the MgO layer 42.

A Ti target is then set in the sputtering apparatus. As shown in FIG. 6, Ti atoms are evolved from the Ti target in the chamber of the sputtering apparatus in the vacuum condition. The Ti atoms are allowed to deposit on the surface of the MgO layer 42. The temperature of the substrate 23 is kept equal to or below 200 degrees Celsius. Accordingly, the room temperature may be kept in the chamber during the deposition of the Ti atoms in this case. Migration of the Ti atoms can thus be prevented on the surface of the substrate 23. A Ti layer 43 having the thickness of 0.4 nm approximately is formed on the surface of the MgO layer 42. Here, crystal grains cannot sufficiently be established in the Ti layer 43.

The Ti layer 43 is subsequently subjected to heat treatment. Heat of 350 degrees Celsius is applied to the Ti layer 43 in the vacuum condition. The application of the heat is maintained for one minute. The substrate 23 may be exposed to infrared radiation in the heat treatment, for example. The applied heat induces crystallization of the Ti layer 43. The MgO layer 42 serves to align the orientation of the crystal grains in a predetermined direction in the Ti layer 43. Fine and uniform crystal grains are established in the Ti layer 43. The first non-magnetic polycrystalline underlayer 33 is in this manner formed on the MgO layer 42.

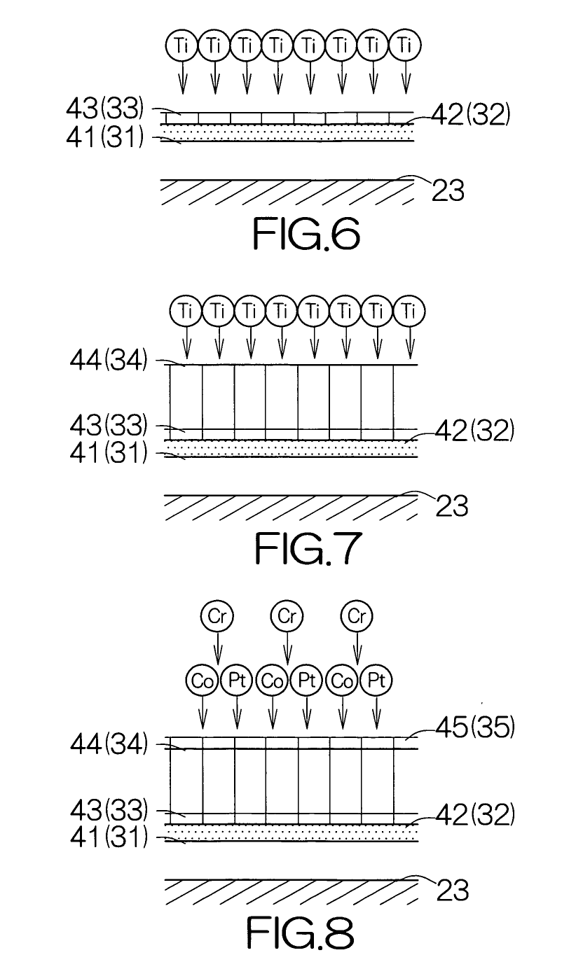

As show in FIG. 7, Ti atoms are subsequently evolved from the Ti target in the chamber in the vacuum condition. The Ti atoms are allowed to deposit on the surface of the Ti layer 43 in the same manner as described above. The temperature of the substrate 23 is kept equal to or below 200 degrees Celsius in the aforementioned manner. Fine and uniform crystal grains thus grow from the individual crystal grains in the Ti layer 43 based on the epitaxy. A Ti layer 44 having the thickness of 3.6 nm approximately is formed on the surface of the Ti layer 43. The Ti layer 44 may be subjected to heat treatment in a condition similar to that to the Ti layer 43. The second non-magnetic polycrystalline underlayer 34 is in this manner formed to have a thickness larger than that of the first non-magnetic polycrystalline underlayer 33.

A CoCrPt target is thereafter set in the sputtering apparatus. As shown in FIG. 8, Co atoms, Cr atoms and Pt atoms are evolved from the CoCrPt target in the chamber of the sputtering apparatus in the vacuum condition. The Co atoms, Cr atoms and Pt atoms are allowed to deposit on the surface of the Ti layer 44. The temperature of the substrate 23 is kept equal to or below 200 degrees Celsius during the deposition of Co atoms, Cr atoms and Pt atoms in the same manner as described above. Fine and uniform crystal grains thus grow from the individual crystal grains in the Ti layer 44 based on the epitaxy. A CoCrPt layer 45 having the thickness of 1.7 nm approximately is in this manner formed on the surface of the Ti layer 44.

The CoCrPt layer 45 is subsequently subjected to heat treatment. Heat of 350 degrees Celsius is applied to the CoCrPt layer 45 in the vacuum condition. The application of the heat is maintained for one minute. The substrate 23 may be exposed to infrared radiation in the heat treatment, for example. The applied heat promotes the crystallization of the CoCrPt layer 45. Fine and uniform crystal grains are established in the CoCrPt layer 45. The first magnetic polycrystalline layer 35 is in this manner formed on the Ti layer 44.

Co atoms, Cr atoms and Pt atoms are then evolved from the CoCrPt target in the chamber of the sputtering apparatus in the vacuum condition, as shown in FIG. 9. The Co atoms, Cr atoms and Pt atoms are allowed to deposit on the surface of the CoCrPt layer 45. The temperature of the substrate 23 is kept equal to or below 200 degrees Celsius during the deposition of Co atoms, Cr atoms and Pt atoms in the same manner as described above. Fine and uniform crystal grains thus grow from the individual crystal grains in the CoCrPt layer 45 based on the epitaxy. A CoCrPt layer 46 having the thickness of 5.8 nm approximately is in this manner formed on the surface of the CoCrPt layer 45. The CoCrPt layer 46 may be subjected to heat treatment in a condition similar to that to the CoCrPt layer 45. The second magnetic polycrystalline layer 36 is in this manner formed to have a thickness larger than that of the first magnetic polycrystalline layer 35.

A vacuum condition is kept during a period between the deposition of the first atoms and the deposition of the fourth atoms, namely between the formation of the Ti layer 43 and the formation of the CoCrPt layer 46 in the aforementioned sputtering process. A vacuum condition should be kept at least during a period between the formation of the Ti layer 43 and the formation of the Ti layer 44 in the process of forming the non-magnetic polycrystalline underlayers 33, 34. Likewise, a vacuum condition should be kept at least during a period between the formation of the CoCrPt layer 45 and the formation of the CoCrPt layer 46 in the process of forming the magnetic polycrystalline layers 35, 36.

The method enables a reliable prevention of migration of Ti atoms during the deposition of the Ti layer 43. A smaller thickness can be set for the Ti layer 43 as compared with the overall thickness of the non-magnetic polycrystalline underlayers 33, 34, so that fine and uniform crystal grains can be established in the crystallization of the Ti layer 43. Migration is still suppressed during the deposition of the Ti atoms to establish a larger thickness after the deposition of the Ti layer 43. Fine and uniform crystal grains can thus be established in the Ti layer 44. Enlargement of the crystal grains is thus reliably prevented in the non-magnetic polycrystalline underlayers 33, 34.

The method also enables a reliable prevention of migration of Co atoms, Cr atoms and Pt atoms during the deposition of the CoCrPt layer 45. A smaller thickness can be set for the CoCrPt layer 45 as compared with the overall thickness of the magnetic polycrystalline layers 35, 36, so that fine and uniform crystal grains can be established in the crystallization of the CoCrPt layer 45. Migration is still suppressed during the deposition of the Co atoms, Cr atoms and Pt atoms to establish a larger thickness after the deposition of the CoCrPt layer 45. Fine and uniform crystal grains can thus be established in the CoCrPt layer 46. Enlargement of the crystal grains is thus reliably prevented in the magnetic polycrystalline layers 35, 36. In addition, the Ti layer 43, 44 serve to reliably establish the orientation of the crystal grains aligned in a predetermined direction in the CoCrPt layers 45, 46.

The inventor has examined the characteristics of the first and second non-magnetic polycrystalline underlayers 33, 34. The inventor sequentially formed the Ti layer 43 of the thickness equal to 0.4 nm and the Ti layer 44 of the thickness equal to 3.6 nm on the surface of the substrate 23 in accordance with the aforementioned method. A CoCrPt layer of the thickness equal to 7.5 nm was formed on the surface of the Ti layer 44. The CoCrPt layer was subjected to heat treatment at 350 degrees Celsius for one minute. A first example was prepared in this manner. The inventor has observed the orientation of crystal grains based on X-ray diffraction.

The inventor prepared first to third comparative examples. A Ti layer of the thickness equal to 3.6 nm and a CoCrPt layer of the thickness equal to 7.5 nm were sequentially formed on the surface of the substrate 23 through sputtering process in the first comparative example. The CoCrPt layer was subjected to heat treatment at 350 degrees Celsius for one minute. A Ti layer of the thickness equal to 3.6 nm and a CoCrPt layer of the thickness equal to 7.5 nm were likewise sequentially formed on the surface of the substrate 23 through sputtering process in the second comparative example. The CoCrPt layer was subjected to heat treatment at 350 degrees Celsius for one minute. In addition, the Ti layer was subjected to heat treatment at 350 degrees Celsius for one minute prior to the deposition of the CoCrPt layer in the second comparative example. A Ti layer of the thickness equal to 3.6 nm and a CoCrPt layer of the thickness equal to 7.5 nm were likewise sequentially formed on the surface of the substrate 23 through sputtering process in the third comparative example. The CoCrPt layer was subjected to heat treatment at 350 degrees Celsius for one minute. In addition, the substrate 23 was subjected to heat treatment at 350 degrees Celsius for one minute prior to the deposition of the Ti layer in the third comparative example. The orientation of crystal grains was observed in the CoCrPt layers of the first to third comparative examples based on X-ray diffraction.

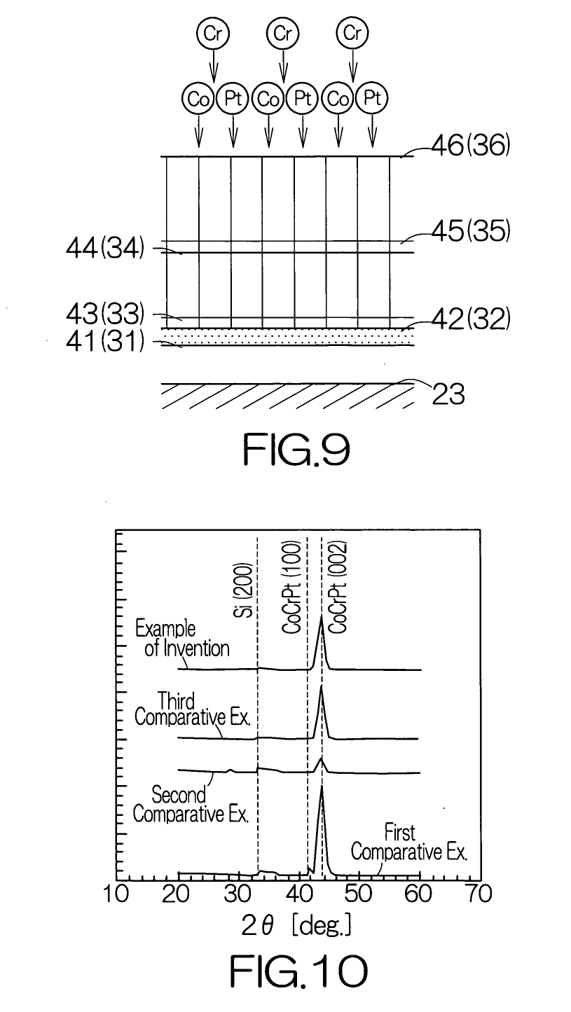

As shown in FIG. 10, it is confirmed that a sufficient amount of crystal grains set the (002) plane in a predetermined direction in the first example of the present embodiment as compared with any of the comparative examples. In addition, the coercivity Hc of 213.3 [kA/m] approximately was measured for the first example of the present embodiment. The product tBr between the residual magnetization Br and the thickness t was obtained at 4.3 [μm·mT] approximately for the first example of the embodiment. On the other hand, the coercivity Hc of 102.7 [kA/m] approximately was measured for the first comparative example. The product tBr between the residual magnetization Br and the thickness t was obtained at 4.6 [μm·mT] approximately for the first comparative example. The coercivity Hc of 102.7 [kA/m] approximately was measured for the second comparative example. The product tBr between the residual magnetization Br and the thickness t was obtained at 5.0 [μm·mT] approximately for the second comparative example. The coercivity Hc of 173.8 [kA/m] approximately was measured for the third comparative example. The product tBr between the residual magnetization Br and the thickness t was obtained at 5.2 [μm·mT] approximately for the third comparative example. The first example of the embodiment exhibits the largest coercivity Hc among the examples.

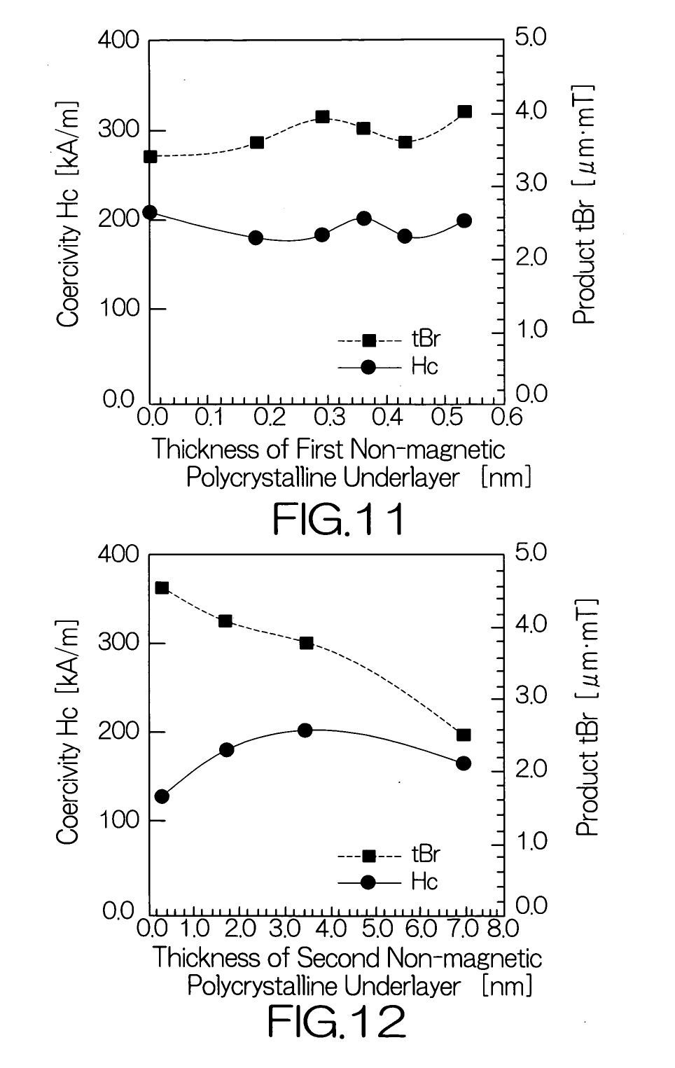

Next, the inventor prepared another examples of the embodiment in accordance with the aforementioned method. The inventor sequentially formed the MgO layer 42 of the thickness equal to 16.7 nm, the ultrathin Ti layer 43, and the Ti layer 44 of the thickness equal to 3.6 nm on the surface of the substrate 23 in these examples. A CoCrPt layer of the thickness equal to 7.5 nm was formed on the surface of the Ti layer 44. The CoCrPt layer was subjected to heat treatment at 350 degrees Celsius for one minute. The inventor prepared second example of the embodiment in this manner. Various thickness was set for the Ti layers 43 of the second examples. The inventor has observed the coercivity Hc and the product tBr between the residual magnetization Br and the thickness t for the CoCrPt layers of the second examples. As is apparent from FIG. 11, all the second examples enjoy higher values for the product tBr between the residual magnetization Br and the thickness t. The Ti layers 43 having a thickness in the range between 0.30 nm and 0.36 nm were preferable to obtain a superior coercivity Hc and product tBr.

Next, the inventor prepared still another examples of the embodiment in accordance with the aforementioned method. The inventor sequentially formed the MgO layer 42 of the thickness equal to 16.7 nm, the Ti layer 43 of the thickness equal to 0.36 nm, and the Ti layer 44 of a predetermined thickness on the surface of the substrate 23 in these examples. A CoCrPt layer of the thickness equal to 7.5 nm was formed on the surface of the Ti layer 44. The CoCrPt layer was subjected to heat treatment at 350 degrees Celsius for one minute. The inventor prepared third examples of the embodiment in this manner. Various thickness was set for the Ti layers 44 of the third examples. The inventor has observed the coercivity Hc and the product tBr between the residual magnetization Br and the thickness t for the CoCrPt layers of the third examples. As is apparent from FIG. 12, the Ti layers 44 having a thickness in the range between 3.0 nm and 4.0 nm were preferable to obtain a superior coercivity Hc and product tBr.

Furthermore, the inventor examined the magnetic characteristics of the first and second magnetic polycrystalline layers 35, 36. The inventor formed a Ti layer of the thickness equal to 3.6 nm on the surface of the substrate 23. A CoCrPt layer 45 of the thickness equal to 1.7 nm and a CoCrPt layer 46 of the thickness equal to 5.8 nm were sequentially formed on the surface of the Ti layer 44 in accordance with the aforementioned method. The inventor prepared fourth examples of the embodiment in this manner. The inventor has observed the orientation of the crystal grains in the CoCrPt layers 45, 46 based on X-ray diffraction. The inventor prepared a fourth comparative example in this case. The inventor sequentially formed a Ti layer of the thickness equal to 3.6 nm and a CoCrPt layer of the thickness equal to 7.5 nm on the surface of the substrate 23 through sputtering process. The CoCrPt layer was subjected to heat treatment at 350 degrees Celsius for one minute. The inventor likewise observed the orientation of the crystal grains in the CoCrPt layer based on X-ray diffraction.

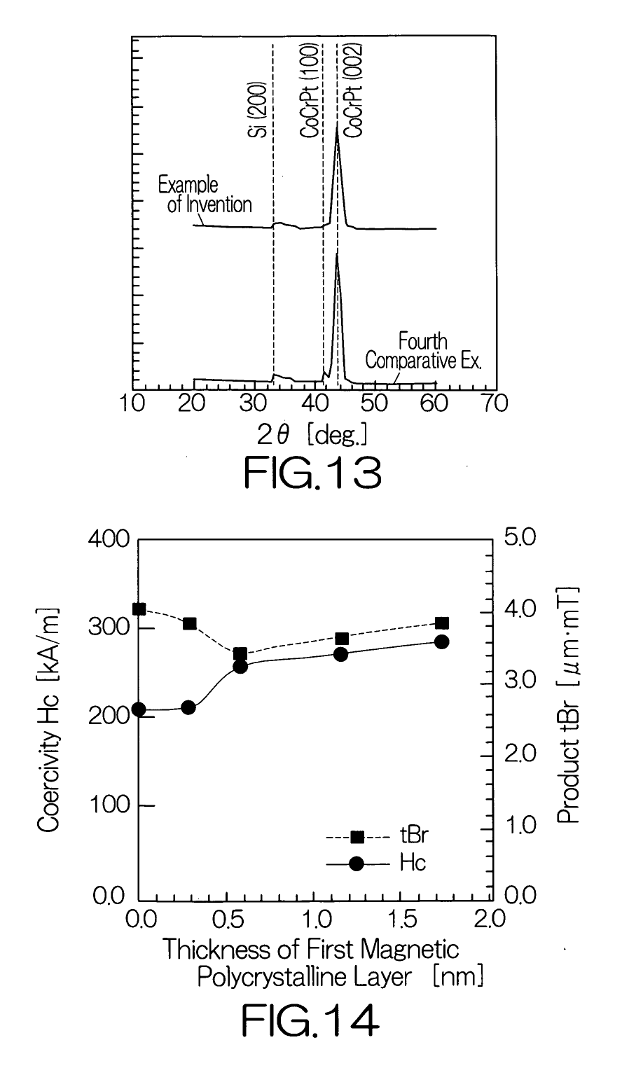

As shown in FIG. 13, it is confirmed that a sufficient amount of crystal grains set the (002) plane in a predetermined direction in the fourth example of the present embodiment as compared with the fourth comparative example. Emergence of the (001) plane was avoided. In addition, the coercivity HC of 181.7 [kA/m] approximately was measured for the fourth example of the present embodiment. The product tBr between the residual magnetization Br and the thickness t was obtained at 2.6 [μm·mT] approximately for the fourth example of the embodiment. On the other hand, the coercivity Hc of 102.7 [kA/m] approximately was measured for the fourth comparative example. The product tBr between the residual magnetization Br and the thickness t was obtained at 4.7 [μm·mT] approximately for the fourth comparative example. The fourth example of the embodiment exhibits a superior coercivity Hc as compared with the fourth comparative example.

Next, the inventor prepared fifth examples of the present embodiment in accordance with the aforementioned method. The inventor sequentially formed the MgO layer 42 of the thickness equal to 16.7 nm, the Ti layer 43 of the thickness equal to 0.53 nm, the Ti layer 44 of the thickness equal to 3.6 nm, the CoCrPt layer 45 of a predetermined thickness and the CoCrPt layer 46 of the thickness equal to 7.5 nm on the surface of the substrate 23 in accordance with the aforementioned method. The CoCrPt layer 46 was subjected to heat treatment at 350 degrees Celsius for one minute. Various thickness was set for the CoCrPt layers 45 in the fifth examples. The inventor has measured the coercivity Hc and the product tBr between the residual magnetization Br and the thickness t for the CoCrPt layers 45, 46 of the fifth examples. As is apparent from FIG. 14, the CoCrPt layer 45 of a thickness in a range between 0.5 nm and 1.7 nm exhibits a superior coercivity Hc and product tBr.

Furthermore, the inventor has examined the utility of the controlling layer 32, namely of the MgO layer 42. The inventor formed the MgO layer 42 of the thickness equal to 11.1 nm on the surface of the substrate 23 in accordance with the aforementioned method. The Ti layer of the thickness equal to 3.6 nm was formed on the surface of the MgO layer 42. The CoCrPt layer 45 of the thickness equal to 1.7 nm and the CoCrPt layer 46 of the thickness equal to 5.8 nm were formed on the surface of the Ti layer in accordance with the aforementioned method. The CoCrPt layer 46 was subjected to heat treatment at 350 degrees Celsius for one minute. The sixth example of the present embodiment was prepared in this manner. The orientation of the crystal grains was observed in the CoCrPt layers 45, 46 based on X-ray diffraction. The inventor also prepared a fifth comparative example in this case. A Ti layer of the thickness equal to 3.6 nm was formed on the surface of the substrate 23. The MgO layer 42 was omitted. The CoCrPt layer 45 of the thickness equal to 1.7 nm and the CoCrPt layer 46 of the thickness equal to 5.8 nm were formed on the surface of the Ti layer in accordance with the aforementioned method. The CoCrPt layer 46 was subjected to heat treatment at 350 degrees Celsius for one minute. The orientation of the crystal grains was observed in the CoCrPt layer 46 based on the X-ray diffraction.

As shown in FIG. 15, it is confirmed that a sufficient amount of crystal grains set the (002) plane in a predetermined direction in the sixth example of the present embodiment as compared with the fifth comparative example. Emergence of the (001) plane was avoided. The utility of the MgO layer 42 has been proven. In addition, the coercivity Hc of 181.7 [kA/m] approximately was measured for the sixth example of the present embodiment. The product tBr between the residual magnetization Br and the thickness t was obtained at 3.3 [μm·mT] approximately for the sixth example of the embodiment. On the other hand, the coercivity Hc of 181.7 [kA/m] approximately was measured for the fifth comparative example. The product tBr between the residual magnetization Br and the thickness t was obtained at 2.6 [μm·mT] approximately for the fifth comparative example. The sixth example of the embodiment exhibits a superior product tBr without reducing the coercivity Hc as compared with the fifth comparative example.

The inventor prepared a seventh example of the present embodiment in accordance with the aforementioned method. The inventor sequentially formed the MgO layer 42 of the thickness equal to 16.7 nm, the Ti layer 43 of the thickness equal to 0.36 nm, the Ti layer 44 of the thickness equal to 3.6 nm, the CoCrPt layer 45 of the thickness equal to 0.59 nm and the CoCrPt layer 46 of the thickness equal to 7.5 nm on the surface of the substrate 23. The CoCrPt layer 46 was subjected to heat treatment at 350 degrees Celsius for one minute. The orientation of the crystal grains was observed in the CoCrPt layers 45, 46 based on X-ray diffraction.

In this case, the inventor prepare sixth to eighth comparative examples. The inventor sequentially formed the MgO layer 42 of the thickness equal to 16.7 nm, a Ti layer of the thickness equal to 3.6 nm and a CoCrPt layer of the thickness equal to 7.5 nm on the surface of the substrate 23 through sputtering process in the sixth comparative example. The CoCrPt layer was subjected to heat treatment at 350 degrees Celsius for one minute. The inventor sequentially formed the MgO layer 42 of the thickness equal to 16.7 nm, the Ti layer 43 of the thickness equal to 0.36 nm and the Ti layer 44 of the thickness equal to 3.6 nm on the surface of the substrate 23 in accordance with the aforementioned method in the seventh comparative example. A CoCrPt layer of the thickness equal to 7.5 nm was further formed on the surface of the Ti layer 44. The CoCrPt layer was subjected to heat treatment at 350 degrees Celsius for one minute. The inventor sequentially formed the MgO layer 42 of the thickness equal to 16.7 nm and a Ti layer of the thickness equal to 3.6 nm on the surface of the substrate 23 through sputtering process in the eighth comparative example. The inventor further formed the CoCrPt layer 45 of the thickness equal to 0.59 nm and the CoCrPt layer 46 of the thickness equal to 7.5 nm on the surface of the Ti layer in accordance with the aforementioned method. The CoCrPt layer 46 was subjected to heat treatment at 350 degrees Celsius for one minute. The orientation of crystal grains was observed in the CoCrPt layers in the sixth to eighth comparative examples based on X-ray diffraction.

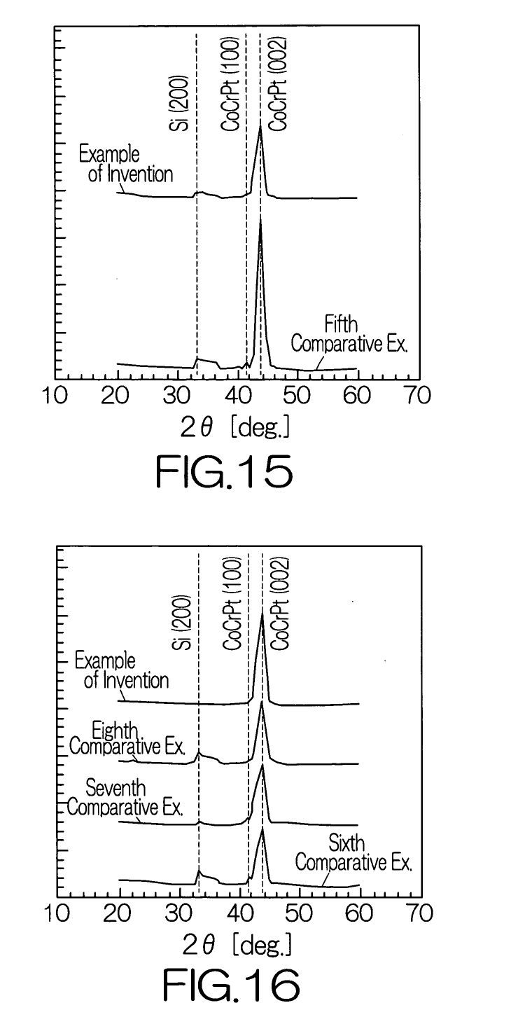

As shown in FIG. 16, it is confirmed that a sufficient amount of crystal grains set the (002) plane in a predetermined direction in the seventh example of the present embodiment as compared with any of the sixth to eighth comparative examples. In addition, the coercivity Hc of 237.0 [kA/m] approximately was measured for the seventh example of the present embodiment. The product tBr between the residual magnetization Br and the thickness t was obtained at 4.6 [μm·mT] approximately for the seventh example of the embodiment. On the other hand, the coercivity Hc of 213.3 [kA/m] approximately was measured for the sixth comparative example. The product tBr between the residual magnetization Br and the thickness t was obtained at 3.4 [μm·mT] approximately for the sixth comparative example. The coercivity Hc of 205.4 [kA/m] approximately was measured for the seventh comparative example. The product tBr between the residual magnetization Br and the thickness t was obtained at 3.8 [μm·mT] approximately for the seventh comparative example. The coercivity Hc of 211.7 [kA/m] approximately was measured for the eighth comparative example. The product tBr between the residual magnetization Br and the thickness t was obtained at 3.6 [μm·mT] approximately for the eighth comparative example. The seventh example of the embodiment exhibits the largest coercivity Hc among the examples.

The axis of easy magnetization may be set in parallel with the surface of the substrate 23 in the aforementioned first and second magnetic polycrystalline layers 35, 36. The first magnetic polycrystalline layer 35 may be formed on the first and second non-magnetic polycrystalline underlayers 33, 34 in the aforementioned manner so as to establish the magnetic anisotropy. In these cases, the aforementioned method may be utilized to form the first and second magnetic polycrystalline layers 35, 36 and the first and second non-magnetic polycrystalline underlayers 33, 34.

A separation layer such as a SiO₂ layer may be formed between the magnetic underlayer 31 or FeTaC layer 41 and the first non-magnetic polycrystalline underlayer 33 or Ti layer 43 in place of the aforementioned controlling layer 32 or MgO layer 42 in the aforementioned magnetic recording disk 13. The separation layer serves to isolate the first non-magnetic polycrystalline layer 33 from the magnetic underlayer 31. As a result, the crystal grains can be aligned in a predetermined direction in the first non-magnetic polycrystalline layer 33 without the influence from the magnetic underlayer 31. Otherwise, a Ru layer may be employed as the first and second non-magnetic polycrystalline layers 33, 34 in the aforementioned magnetic recording disk 13.

1. A method of making a multilayered structure film, comprising:
depositing first atoms on a surface of an object;
subjecting the first atoms to heat treatment so as to form a first polycrystalline layer; and
depositing second atoms on a surface of the first polycrystalline layer so as to form a second polycrystalline layer having a thickness larger than that of the first polycrystalline layer.

2. The method according to claim 1, wherein said first atoms include at least an element included in the second atoms.

3. The method according to claim 2, wherein said first and second atoms are Ti atoms.

4. The method according to claim 2, wherein said first and second atoms form an alloy including Co and Cr.

5. The method according to claim 1, wherein a vacuum condition is kept between deposition of the first atoms and deposition of the second atoms.

6. The method according to claim 1, further comprising:
depositing third atoms on a surface of the second crystalline layer;
subjecting the third atoms to heat treatment so as to from a third crystalline layer; and
depositing fourth atoms on a surface of the third polycrystalline layer so as to form a fourth polycrystalline layer having a thickness larger than that of the third polycrystalline layer.

7. The method according to claim 6, wherein said first and second atoms are Ti atoms while said third and fourth atoms form an alloy including Co and Cr.

8. The method according to claim 7, further comprising covering the surface of the object, prior to deposition of the first atoms, with a controlling layer including crystal grains oriented in a predetermined direction.

9. The method according to claim 8, wherein said controlling layer is made of MgO.

10. The method according to claim 6, wherein a vacuum condition is kept between deposition of the first atoms and deposition of the fourth atoms.

11. A multilayered structure film comprising:
a first polycrystalline layer including crystal grains adjacent each other; and
a second polycrystalline layer including at least an element included in the first polycrystalline layer, said second polycrystalline layer extending on a surface of the first polycrystalline layer by a thickness larger than that of the first polycrystalline layer, wherein
said second polycrystalline layer includes crystal grains growing from the crystal grains of the first polycrystalline layer.

12. The multilayered structure film according to claim 11, wherein said first and second polycrystalline layers are made of Ti.

13. The multilayered structure film according to claim 11, wherein said first and second polycrystalline layers are made of an alloy containing Co and Cr.

14. The multilayered structure film according to claim 12, further comprising a controlling layer receiving said first polycrystalline layer, said controlling layer including crystal grains oriented in a predetermined direction.

15. A magnetic recording medium comprising:
a first non-magnetic polycrystalline underlayer including crystal grains adjacent each other;
a second non-magnetic polycrystalline underlayer including at least an element included in the first non-magnetic polycrystalline underlayer, said second non-magnetic polycrystalline underlayer extending on a surface of the first non-magnetic polycrystalline underlayer by a thickness larger than that of the first non-magnetic polycrystalline underlayer; and
a magnetic layer extending on a surface of the second non-magnetic polycrystalline underlayer, wherein
said second non-magnetic polycrystalline underlayer includes crystal grains growing from the crystal grains of the first non-magnetic polycrystalline underlayer.

16. The magnetic recording medium according to claim 15, wherein said magnetic layer has an axis of easy magnetization in a perpendicular direction perpendicular to the surface of the second non-magnetic polycrystalline underlayer.

17. The magnetic recording medium according to claim 16, further comprising:
a non-magnetic layer receiving said first non-magnetic polycrystalline layer; and
a magnetic underlayer receiving the non-magnetic layer, said magnetic underlayer having an axis of easy magnetization in a direction parallel to the surface of the second non-magnetic polycrystalline underlayer.

18. The magnetic recording medium according to claim 15, wherein said magnetic layer comprises:
a first magnetic polycrystalline layer including crystal grains adjacent each other on the surface of the second non-magnetic polycrystalline underlayer;
a second magnetic polycrystalline layer including at least an element included in the first magnetic polycrystalline layer, said second magnetic polycrystalline layer extending on a surface of the first magnetic polycrystalline layer by a thickness larger than that of the first magnetic polycrystalline layer, wherein
said second magnetic polycrystalline layer includes crystal grains growing from the crystal grains of the first magnetic polycrystalline layer.

19. The magnetic recording medium according to claim 18, wherein said first and second magnetic polycrystalline layers have an axis of easy magnetization in a perpendicular direction perpendicular to the surface of the second non-magnetic polycrystalline underlayer.

20. The magnetic recording medium according to claim 19, further comprising:
a non-magnetic layer receiving said first non-magnetic polycrystalline underlayer; and
a magnetic underlayer receiving the non-magnetic layer, said magnetic underlayer having an axis of easy magnetization in a direction parallel to the surface of the second non-magnetic polycrystalline underlayer.

21. A magnetic recording medium comprising:
a non-magnetic polycrystalline underlayer;
a first magnetic polycrystalline layer including crystal grains adjacent each other on a surface of the non-magnetic polycrystalline underlayer;
a second magnetic polycrystalline layer including at least an element included in the first magnetic polycrystalline layer, said second magnetic polycrystalline layer extending on a surface of the first magnetic polycrystalline layer by a thickness larger than that of the first magnetic polycrystalline layer, wherein
said second magnetic polycrystalline layer includes crystal grains growing from the crystal grains of the first magnetic polycrystalline layer.

22. The magnetic recording medium according to claim 21, wherein said first and second magnetic polycrystalline layers have an axis of easy magnetization in a perpendicular direction perpendicular to the surface of the non-magnetic polycrystalline underlayer.

23. The magnetic recording medium according to claim 22, further comprising:
a non-magnetic layer receiving said non-magnetic polycrystalline underlayer; and
a magnetic underlayer receiving the non-magnetic layer, said magnetic underlayer having an axis of easy magnetization in a direction parallel to the surface of the non-magnetic polycrystalline underlayer.
